(19) United States
(12) Patent Application Publication
(10) Pub. No.: US 2024/0027914 A1
(43) Pub. Date: Jan. 25, 2024

(54) ACTUATOR-SENSOR DEVICE AND LITHOGRAPHY APPARATUS

(71) Applicant: Carl Zeiss SMT GmbH, Oberkochen (DE)

(72) Inventors: Holger Sontag, Heidenheim (DE); Stefan Seitz, Aalen (DE); Mario Muetzel, Oberkochen (DE); Philipp Torres Da Silva, Grossbottwar (DE); Stefan Krone, Aalen (DE); Petra Linzmayer, Manching (DE); Waldemar Lange, Neulehe (DE); Kai Kunze, Schwaebisch-Gmeund (DE)

(21) Appl. No.: 18/480,263

(22) Filed: Oct. 3, 2023

Related U.S. Application Data
(63) Continuation of application No. PCT/EP2022/058953, filed on Apr. 5, 2022.

(30) Foreign Application Priority Data
Apr. 15, 2021 (DE) 102021203721.6

(51) Int. Cl. G03F 7/00

(52) U.S. Cl. CPC G03F 7/7015; G03F 7/7085

(57) ABSTRACT

An actuator-sensor device for an optics module of a lithography apparatus comprises: an actuator-sensor unit having an actuator and a sensor; a control unit electrically connected to the actuator-sensor unit; and a support element which on a first supporting side of same supports the actuator-sensor unit and which on a second supporting side of same supports the control unit, with the second supporting side being opposite to the first supporting side.

### CROSS-REFERENCE TO RELATED APPLICATIONS

The present application is a continuation of, and claims benefit under 35 USC 120 to, international application PCT/EP2022/058953, filed Apr. 5, 2022, which claims benefit under 35 USC 119 of German Application No 10 2021 203 721.6, filed Apr. 15, 2021. The entire disclosure of each these applications is incorporated by reference herein.

### FIELD

The present disclosure relates to an actuator-sensor device for a lithography apparatus, and to a lithography apparatus comprising such an actuator-sensor device.

### BACKGROUND

Microlithography is used for the production of microstructured components, for example integrated circuits. The microlithography process is carried out using a lithography apparatus, which has an illumination system and a projection system. The image of a mask (reticle) illuminated with the aid of the illumination system is projected here with the aid of the projection system onto a substrate, for example a silicon wafer, which is coated with a light-sensitive layer (photoresist) and arranged in the image plane of the projection system, in order to transfer the mask structure to the light-sensitive coating of the substrate.

Driven by the desire for ever smaller structures in the production of integrated circuits, currently under development are EUV lithography apparatuses that use light with a wavelength in the range of 0.1 nm to 30 nm, in particular 13.5 nm. In the case of such EUV lithography apparatuses, because of the high absorption of light of this wavelength by most materials, reflective optical units, that is to say mirrors, are typically used instead of—as previously—refractive optical units, that is to say lens elements.

The minors may for example be fastened to a supporting frame (force frame) and be designed as at least partially manipulable, in order to allow a movement of a respective mirror in up to six degrees of freedom, and consequently a relatively highly accurate positioning of the minors in relation to one another, such as in the pm range. This can help allow changes in the optical properties that occur for instance during the operation of the lithography apparatus, for example as a result of thermal influences, to be compensated for.

To detect and change the pose of the minors, the lithography apparatus can have an actuator-sensor device. The latter can comprise actuator-sensor units having a sensor and an actuator, and also control units which activate the actuator-sensor units.

To create a vacuum seal between the mirrors and the control units, the actuator-sensor units and the control units can be arranged in a vacuum-tight housing. For this purpose, the actuator-sensor units can be first arranged in the housing and then the control units can be integrated in the housing from the same side. Vacuum seals can be provided between the actuator-sensor units and the housing.

When repairing, servicing, and/or replacing the actuator-sensor units, it is generally desirable for the control units to be removed first in order to be able to access the actuator-sensor units.

### SUMMARY

The present disclosure seeks to provide an improved actuator-sensor device.

According to a first aspect, an actuator-sensor device for an optical module of a lithography apparatus is proposed. The actuator-sensor device comprises:
an actuator-sensor unit having an actuator and a sensor;
a control unit, which is electrically connected to the actuator-sensor unit; and
a supporting element which supports the actuator-sensor unit on a first supporting side of same and the control unit on a second supporting side of same, the second supporting side facing the first supporting side.

The actuator-sensor unit and the control unit can be supported in particular by different supporting sides of the supporting element. This can allow the actuator-sensor unit to be repaired and/or replaced without removing the control unit from the supporting element. In addition, the control unit can be repaired and/or replaced without removing the actuator-sensor unit from the supporting element. This means that repair and/or replacement of the electronic components (actuator-sensor unit and control unit) held by the supporting element can be carried out with little effort. A non-operating time during which the actuator-sensor device is not in operation can be reduced.

The optical module can be part of the illumination system of the lithography apparatus. The optical module can comprise in particular a plurality of optical elements, which are individually controllable by an assigned actuator. The optical elements can be mirrors or lens elements. The optical module can be a facet minor having a plurality of mirror facets, which are optical elements. Each mirror facet is individually activatable in respect of its pose.

The actuator-sensor unit can comprise at least one sensor and one actuator. However, it may also comprise a plurality of sensors and/or actuators. The actuator-sensor unit can be assigned to an optical element of the lithography apparatus, for example to a mirror facet.

The sensor can be suitable in particular for detecting the pose of the associated optical element. Each optical element can have six degrees of freedom, specifically three translational degrees of freedom in each case along a first spatial direction or x-direction, a second spatial direction or y-direction, and a third spatial direction or z-direction, and also three rotational degrees of freedom each about the x-direction, the y-direction, and the z-direction. In other words, the sensor can determine or describe a position and an orientation of the optical element using the six degrees of freedom. The pose refers here to the position and orientation of the optical element.

The actuator can be suitable in particular for moving the associated optical element. In this case, the actuator can change both the position and the orientation of the optical element.

The control unit can be used to control the actuator-sensor unit. The control unit can be communicatively connected to the actuator-sensor unit in order to receive sensor data from the sensor and/or to send control data to the actuator. The control unit can be suitable for determining the control data on the basis of the received sensor data. The control unit and actuator-sensor unit are electronic modules.

In particular, the fact that the control unit is electrically connected to the actuator-sensor unit means that there is a permanent or detachable electrical contact between the control unit and the actuator-sensor unit. This electrical connection can be made by directly contacting contact points of the control unit and the actuator-sensor unit. It is also conceivable that the electrical connection is made via a cable and/or an electrically conductive element of the supporting element. The electrical connection or contact between the control unit and the actuator-sensor unit can be used to energize the units and/or to communicate between the two units.

The supporting element can also be referred to as a supporting frame or supporting housing. “Supporting” means in particular “holding” in connection with the supporting element. The fact that the actuator-sensor unit is supported by the first supporting side means in particular that the actuator-sensor unit is arranged on the first supporting side and can be connected to the first supporting side. To connect the actuator-sensor unit to the first supporting side, the actuator-sensor unit can be arranged at least partially in a first receptacle of the first supporting side and/or can be fastened with a fastening element (for example with screws) to the first supporting side. For this purpose, the supporting element can have fittings for screwing the actuator-sensor unit to the first supporting side and/or for positioning the screw connection.

The fact that the control unit is supported by the second supporting side means in particular that the control unit is arranged on the second supporting side and can be connected to the second supporting side. To connect the control unit to the second supporting side, the control unit can be arranged at least partially in a second receptacle of the second supporting side and/or can be fastened with a fastening element (for example with screws) to the second supporting side. For this purpose, the supporting element can have fittings for screwing the control unit to the second supporting side and/or for positioning the screw connection.

In a state in which the actuator-sensor unit and the control unit are supported by the supporting element, the actuator-sensor unit and the control unit can be in contact. The actuator-sensor unit and the control unit can also be connected to each other in this state. The actuator-sensor unit and the control unit can be in particular electrically connected to each other by being arranged on the respective supporting sides of the supporting element.

The fact that the second supporting side faces the first supporting side means in particular that the first and second supporting sides are opposite sides of the supporting element. The supporting element can support the control unit and the actuator-sensor unit in such a way that the supporting element is at least partially present between the control unit and the actuator-sensor unit. In an arrangement of the actuator-sensor device, in which the first supporting side is at the bottom and the second supporting side is at the top, the actuator-sensor unit can be fastened from below to the supporting element, while the control unit can be fastened from above to the supporting element. An installation direction of the actuator-sensor unit can run in particular parallel, but in the opposite direction to the installation direction of the control unit. The actuator-sensor unit and the control unit can therefore be removed individually from the supporting element.

The actuator-sensor device can comprise at least one actuator-sensor unit and one control unit. However, it can comprise a plurality of actuator-sensor units and/or a plurality of control units. The supporting element can support a plurality of actuator-sensor units arranged next to one another on the first supporting side and/or a plurality of control units arranged next to one another on the second supporting side. Each actuator-sensor unit can have an associated control unit. However, it is also possible to electrically connect and control a control unit having a plurality of actuator-sensor units.

According to an embodiment, the supporting element has at least one opening which pierces the supporting element from the first supporting side to the second supporting side. The actuator-sensor unit and the control unit are in contact through the opening and are thus electrically connected to each other.

In particular, the opening can allow direct contact between the actuator-sensor unit and the control unit. The contact points of the actuator-sensor unit and the control unit can be in contact through the opening, thus enabling the electrical connection.

According to an embodiment, the supporting element has, on the first supporting side, a first receptacle into which the actuator-sensor unit is at least partially inserted. The supporting element has, on the second supporting side, a second receptacle into which the control unit is at least partially inserted, the first receptacle facing the second receptacle.

The receptacles can be used to position the actuator-sensor unit and/or the control unit on the supporting element. The receptacles can be in particular shaped in such a way that the actuator-sensor unit and/or the control unit can be inserted into the supporting element only in a single orientation. This can help prevent incorrect assembly of the actuator-sensor device.

The receptacles can furthermore be used to hold the actuator-sensor unit and/or the control unit on the supporting element.

According to an embodiment, the sensor is suitable for detecting a physical property, in particular a pose, of an optical element of the lithography apparatus. Alternatively or in addition, the actuator is suitable for changing the pose of the optical element.

According to an embodiment, the actuator-sensor unit is detachably connected to the first supporting side of the supporting element, and/or the control unit is detachably connected to the second supporting side of the supporting element.

A detachable connection should be understood as meaning in particular a connection which can be released without damaging and/or destroying the connected components. Such a detachable connection is made possible, for example, via the plug-in connection described above, in which the actuator-sensor unit and/or the control unit is inserted into a corresponding receptacle, and/or via a screw connection. The actuator-sensor unit and/or the control unit can be removed from the supporting element and/or replaced as often as desired because of the detachable connection. This results in a modular actuator-sensor device.

The optical module can be arranged in a vacuum environment. However, at least the control unit can be located in an environment in which normal pressure prevails. The actuator-sensor device can be used to seal the control unit in relation to the optical module in a vacuum-tight manner.

According to an embodiment:
the actuator-sensor unit has a first contact element;
the control unit has a printed circuit board with a second contact element; and
the supporting element supports the actuator-sensor unit and the control unit in such a way that the first contact element makes contact with the second contact element.

The second contact element can be designed as a gold-coated surface on the printed circuit board. In particular, a surface of the second contact element can be larger than a surface of the first contact element to allow compensation for tolerances. This can help ensure the electrical connection between the control unit and the actuator-sensor unit even after one of the units has been replaced.

A number of first contact elements can correspond to a number of second contact elements. If only a single actuator-sensor unit is connected to a control unit, N first contact elements and N second contact elements can be provided (where N≥1, for example 40≥N≥1). If M (M≥2) actuator-sensor units are connected to a control unit, N first contact elements and P=M*N second contact elements can be provided.

According to an embodiment, the first contact element is designed as a pin, in particular as a spring contact pin.

The first contact element designed as a pin can protrude through the opening in the supporting element so as to be in contact with the second contact element of the printed circuit board and thus to enable the electrical connection between the actuator-sensor unit and the control unit.

Spring contact pins are contacting pins with a spring that allow an end piece of the pin to be moved axially. The use of such spring contact pins can help allow reliable electrical contact between the first and second contact elements without too much pressure being applied to the contact elements. The spring contact pins can help allow compensation for tolerances in an axial direction of the spring contact pins. Pogo pins, for example, can be used as the spring contact pins.

According to an embodiment:
the control unit has a main body with a printed circuit board connection for supporting the printed circuit board;
the printed circuit board connection comprises at least two pins;
the printed circuit board has at least two holes into which the pins are introduced, with at least one of the holes being an elongate hole.

To form the control unit, the printed circuit board can be assembled together with the main body. The printed circuit board and the main body can thus form separate components. The main body can comprise a heat sink. Such heat sinks will be described in more detail below.

The printed circuit board connection can be formed integrally with the material of the main body. “Integrally with the material” means in particular that the main body and the printed circuit board connection are made of one component and a single material.

The positions and sizes of the respective holes in the printed circuit board can correspond to those of the pins of the printed circuit board connection. This means in particular that the respective holes lie opposite the pins, and that the diameters of the respective holes are equal to or slightly larger than the diameters of the pins.

The hole which is not an elongate hole can be a circular hole. This hole can block a translational movement of the printed circuit board on the main body.

By forming one of the holes as an elongate hole, compensation for tolerances is possible. The elongate hole namely can help allow the pin inserted therein to move along the longitudinal direction of the elongate hole. The combination of elongate hole and pin can block the rotation of the printed circuit board on the heat sink about an axis running perpendicular to the printed circuit board. However, the positioning of the printed circuit board is not overdetermined by the use of the elongate hole on the printed circuit board. Therefore, even printed circuit boards, the holes in which do not have precisely the desired dimensions or positions due to manufacturing tolerances, can nevertheless be attached to the main body.

The printed circuit board can also be fixed to the main body via fastening screws.

According to an embodiment:
the supporting element has a metal strip for dissipating heat;
the control unit has a metal heat sink; and
the supporting element supports the actuator-sensor unit and the control unit in such a way that the heat sink is in contact with the metal strip.

The heat sink and the metal strip can be made of a material having high thermal conductivity, such as aluminum or copper. The heat sink can be used to dissipate heat from the control unit. This can help prevent the control unit from becoming too hot and being damaged by the heat. The heat can be dissipated through the metal strip, which is in contact with the heat sink. The metal strip can be part of the supporting frame. In particular, heat sinks of a plurality of control units can be contacted by the metal strip.

According to an embodiment:
the heat sink has at least two lugs;
the metal strip has at least two lug receptacles; and
the supporting element supports the actuator-sensor unit and the control unit in such a way that the two lugs of the heat sink are received by the two lug receptacles.

The two lugs can be formed integrally with the material of the heat sink. The lug receptacles can be formed as recesses in the metal strip. The lug receptacles can be dimensioned and positioned in such a way that they can accommodate the two lugs. For example, the lugs are inserted into the lug receptacles along a direction running perpendicularly to the printed circuit board and/or to the second supporting side.

Owing to the fact that at least two lugs and corresponding lug receptacles are provided, rotation of the control unit relative to the supporting element about an axis running perpendicularly to the printed circuit board and/or to the second supporting side can be prevented. In addition, the lugs and corresponding lug receptacles can generally serve for positioning the control unit on the second supporting side.

According to an embodiment:
the control unit has at least one positioning peg;
the supporting element has at least one peg receptacle; and
the supporting element supports the control unit in such a way that the peg receptacle receives the positioning peg.

The positioning peg can be provided on the printed circuit board or on the main body. It can be formed integrally with the material of the main body. The positioning peg can be guided by the printed circuit board through a corresponding hole therein. Since the positioning peg is guided into the peg receptacle, it can help ensure that the control unit is positioned as intended relative to the supporting frame.

According to an embodiment, the main body of the control unit has printed circuit board protection elements which protrude laterally beyond the printed circuit board.

The printed circuit board protection elements can be formed integrally with the material of the main body, in particular with the heat sink. They can be projections of the main body that protrude further from the main body than the printed circuit board.

When the control unit is mounted on the supporting element, the printed circuit board is usually concealed. In order to prevent the printed circuit board from being damaged due to being bumped during the only partly guided assembly, the printed circuit board protection elements can be provided. The printed circuit board protection elements can protect the printed circuit board in case of a translational offset of the printed circuit board relative to the supporting element and/or in case of rotation of the printed circuit board relative to the supporting element.

According to an embodiment, the main body has two printed circuit board protection elements which are arranged at diagonally opposite corners of the printed circuit board.

The two printed circuit board protection elements arranged at diagonally opposite corners of the printed circuit board can help provide optimum protection of the printed circuit board.

According to a second aspect, a control unit for the actuator-sensor device according to the first aspect or according to an embodiment of the first aspect is provided.

The features described within the scope of the description of the first aspect relating to the control unit apply mutatis mutandis to the control unit according to the second aspect. In particular, the control unit comprises a printed circuit board having a second contact element, a heat sink and/or a positioning pin.

According to a third aspect, a supporting element for the actuator-sensor device according to the first aspect or according to an embodiment of the first aspect is provided.

The features described within the scope of the description of the first aspect relating to the supporting element apply mutatis mutandis to the supporting element according to the third aspect. In particular, the supporting element comprises opposite first and second supporting sides, first and/or second receptacles and/or an opening.

According to a fourth aspect, an actuator-sensor unit for the actuator-sensor device according to the first aspect or according to an embodiment of the first aspect is provided.

The features described within the scope of the description of the first aspect relating to the actuator-sensor unit apply mutatis mutandis to the actuator-sensor unit according to the fourth aspect. In particular, the actuator-sensor unit comprises a sensor and an actuator, first contact element, and/or a peg receptacle.

According to a fifth aspect, a lithography apparatus having an actuator-sensor device according to the first aspect or according to an embodiment of the first aspect is provided.

The lithography apparatus can be an EUV or DUV lithography apparatus, in particular. EUV stands for “extreme ultraviolet” and refers to a wavelength of the working light of between 0.1 and 30 nm. DUV stands for “deep ultraviolet” and refers to a wavelength of the working light of between 30 and 250 nm.

The embodiments and features described for the actuator-sensor device apply mutatis mutandis to the proposed lithography apparatus, and vice versa.

“A” or “an” in the present case should not necessarily be understood to be restricted to precisely one element. Rather, a plurality of elements, such as two, three or more, may also be provided. Nor should any other numeral used here be understood to the effect that there is a restriction to exactly the stated number of elements. Instead, unless indicated otherwise, numerical deviations upward and downward are possible.

Further possible implementations of the disclosure also include combinations which were not mentioned explicitly of features or embodiments described above or hereinafter with respect to the exemplary embodiments. In this case, a person skilled in the art will also add individual aspects as improvements or supplementations to the respective basic form of the disclosure.

Further advantageous refinements and aspects of the disclosure are the subject matter of the dependent claims and also of the exemplary embodiments of the disclosure that are described below. In addition, the disclosure will be explained in detail hereinafter on the basis of preferred embodiments with reference to the appended figures.

### BRIEF DESCRIPTION OF THE DRAWINGS

FIG. 1 schematically shows a projection exposure apparatus for EUV projection lithography in a meridional section.

FIG. 2 shows an actuator-sensor device.

FIG. 3 shows a control unit for the actuator-sensor device from FIG. 2.

FIG. 4 shows the control unit of FIG. 3 in top view.

FIG. 5 shows a coupling between the control unit and a supporting element for the actuator-sensor device from FIG. 2.

FIG. 6 schematically shows a section through the actuator-sensor device from FIG. 2.

FIG. 7 shows a detail from FIG. 6, which shows the connection between the control unit and an actuator-sensor unit.

### DETAILED DESCRIPTION

Unless indicated otherwise, elements that are identical or functionally identical have been provided with the same reference signs in the figures. It should also be noted that the illustrations in the figures are not necessarily true to scale.

An embodiment of an illumination system 2 of the projection exposure apparatus (lithography apparatus) 1 has, in addition to a light or radiation source 3, an illumination optical unit 4 for illuminating an object field 5 in an object plane 6. In an alternative embodiment, the light source 3 may also be provided as a module separate from the rest of the illumination system. In this case, the illumination system 2 does not comprise the light source 3.

A reticle 7 arranged in the object field 5 is exposed. The reticle 7 is held by a reticle holder 8. The reticle holder 8 is displaceable in particular in a scanning direction by way of a reticle displacement drive 9.

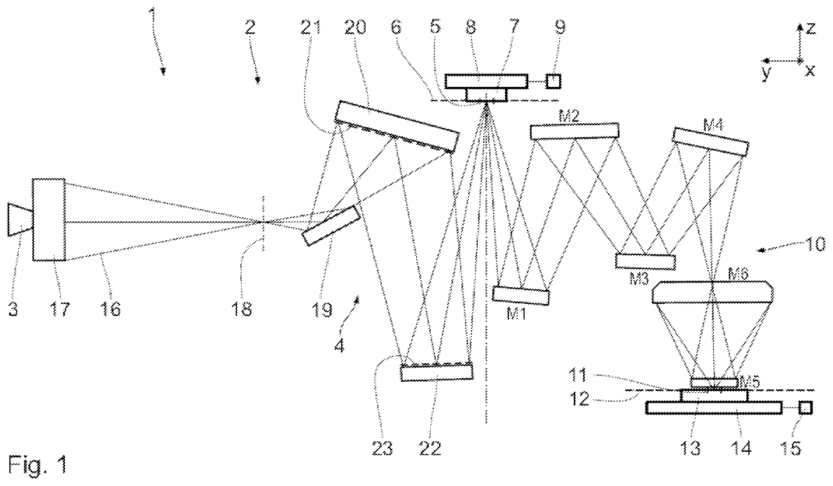

A Cartesian xyz-coordinate system is shown in FIG. 1 for explanation purposes. The x-direction runs perpendicularly to the plane of the drawing. The y-direction runs horizontally, and the z-direction runs vertically. The scanning direction runs along the y-direction in FIG. 1. The z-direction runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle that differs from 0° between the object plane 6 and the image plane 12 is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable in particular along the y-direction by way of a wafer displacement drive 15. The displacement, firstly, of the reticle 7 by way of the reticle displacement drive 9 and, secondly, of the wafer 13 by way of the wafer displacement drive 15 can be implemented so as to be mutually synchronized.

The radiation source 3 is an EUV radiation source. The radiation source 3 emits, in particular, EUV radiation 16, which is also referred to below as used radiation, illumination radiation or illumination light. In particular, the used radiation has a wavelength in the range between 5 nm and 30 nm. The radiation source 3 can be a plasma source, for example an LPP (laser produced plasma) source or a GDPP (gas discharge produced plasma) source. It may also be a synchrotron-based radiation source. The radiation source 3 may be a free electron laser (FEL).

The illumination radiation 16 emerging from the radiation source 3 is focused by a collector 17. The collector 17 may be a collector with one or more ellipsoidal and/or hyperboloidal reflection surfaces. The illumination radiation 16 can be incident on the at least one reflection surface of the collector 17 with grazing incidence (GI), that is to say at angles of incidence of greater than 45°, or with normal incidence (NI), that is to say at angles of incidence of less than 45°. The collector 17 can be structured and/or coated firstly for optimizing its reflectivity for the used radiation and secondly for suppressing extraneous light.

Downstream of the collector 17, the illumination radiation 16 propagates through an intermediate focus in an intermediate focal plane 18. The intermediate focal plane 18 can represent a separation between a radiation source module, having the radiation source 3 and the collector 17, and the illumination optical unit 4.

The illumination optical unit 4 comprises a deflection minor 19 and, arranged downstream thereof in the beam path, a first facet mirror 20. The deflection mirror 19 can be a plane deflection mirror or, alternatively, a minor with a beam-influencing effect that goes beyond the purely deflecting effect. As an alternative or in addition, the deflection mirror 19 may be embodied as a spectral filter that separates a used light wavelength of the illumination radiation 16 from extraneous light of a wavelength deviating therefrom. If the first facet mirror 20 is arranged in a plane of the illumination optical unit 4 that is optically conjugate to the object plane 6 as a field plane, it is also referred to as a field facet minor. The first facet minor 20 comprises a multiplicity of individual first facets 21, which are also referred to below as field facets. FIG. 1 depicts only some of the facets 21 by way of example.

The first facets 21 can be embodied as macroscopic facets, in particular as rectangular facets or as facets with an arcuate or partly circular edge contour. The first facets 21 may be embodied as plane facets or alternatively as convexly or concavely curved facets.

As is known for example from DE 10 2008 009 600 A1, the first facets 21 themselves can also each be composed of a multiplicity of individual mirrors, in particular a multiplicity of micromirrors. The first facet mirror 20 may in particular be in the form of a microelectromechanical system (MEMS system). For details, reference is made to DE 10 2008 009 600 A1.

The illumination radiation 16 travels horizontally, that is to say along the y-direction, between the collector 17 and the deflection mirror 19.

In the beam path of the illumination optical unit 4, a second facet mirror 22 is arranged downstream of the first facet mirror 20. If the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or hexagonal boundary, or may alternatively be facets composed of micromirrors. In this regard, reference is also made to DE 10 2008 009 600 A1.

The second facets 23 may have plane reflection surfaces or alternatively reflection surfaces with a convex or concave curvature.

The illumination optical unit 4 consequently forms a double-faceted system. This fundamental principle is also referred to as a fly's eye integrator.

It may be advantageous to arrange the second facet mirror 22 not exactly in a plane that is optically conjugate to a pupil plane of the projection optical unit 10. In particular, the pupil facet mirror 22 can be arranged so as to be tilted relative to a pupil plane of the projection optical unit 7, as is described, for example, in DE 10 2017 220 586 A1.

The individual first facets 21 are imaged into the object field 5 using the second facet mirror 22. The second facet mirror 22 is the last beam-shaping mirror or indeed the last mirror for the illumination radiation 16 in the beam path upstream of the object field 5.

In a further embodiment of the illumination optical unit 4 (not illustrated), a transfer optical unit can be arranged in the beam path between the second facet mirror 22 and the object field 5, the transfer optical unit contributing to the imaging of the first facets 21 into the object field 5, in particular. The transfer optical unit can comprise exactly one mirror or, alternatively, two or more mirrors, which are arranged in succession in the beam path of the illumination optical unit 4. The transfer optical unit can in particular comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the field facet mirror 20, and the pupil facet mirror 22.

The deflection mirror 19 can also be dispensed with in a further embodiment of the illumination optical unit 4, and so the illumination optical unit 4 can then have exactly two mirrors downstream of the collector 17, specifically the first facet mirror 20 and the second facet mirror 22.

The imaging of the first facets 21 into the object plane 6 via the second facets 23 or using the second facets 23 and a transfer optical unit is often only approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are likewise possible. The projection optical unit 10 is a doubly obscured optical unit. The penultimate mirror M5 and the last mirror M6 each have a through opening for the illumination radiation 16. The projection optical unit 10 has an image-side numerical aperture that is greater than 0.5 and may also be greater than 0.6 and may be for example 0.7 or 0.75.

Reflection surfaces of the mirrors Mi can be embodied as freeform surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi can have highly reflective coatings for the illumination radiation 16. These coatings can be designed as multilayer coatings, in particular with alternating layers of molybdenum and silicon.

The projection optical unit 10 has a large object-image offset in the y-direction between a y-coordinate of a center of the object field 5 and a y-coordinate of the center of the image field 11. In the y-direction, this object-image offset can be of approximately the same magnitude as a z-distance between the object plane 6 and the image plane 12.

The projection optical unit 10 may in particular have an anamorphic form. In particular, it has different imaging scales βx, βy in the x- and y-directions. The two imaging scales βx, βy of the projection optical unit 10 can lie at (βx, βy)=(+/−0.25, /+−0.125). A positive imaging scale β means imaging without image inversion. A negative sign for the imaging scale β means imaging with image inversion.

The projection optical unit 10 consequently leads to a reduction in size with a ratio of 4:1 in the x-direction, which is to say in a direction perpendicular to the scanning direction.

The projection optical unit 10 leads to a reduction in size of 8:1 in the y-direction, which is to say in the scanning direction.

Other imaging scales are likewise possible. Imaging scales with the same signs and the same absolute values in the x-direction and y-direction are also possible, for example with absolute values of 0.125 or 0.25.

The number of intermediate image planes in the x-direction and in the y-direction in the beam path between the object field 5 and the image field 11 can be the same or can differ depending on the embodiment of the projection optical unit 10. Examples of projection optical units with different numbers of such intermediate images in the x- and y-directions are known from US 2018/0074303 A1.

In each case one of the pupil facets 23 is assigned to exactly one of the field facets 21 for forming in each case an illumination channel for illuminating the object field 5. This may in particular produce illumination according to the Köhler principle. The far field is decomposed into a multiplicity of object fields 5 with the aid of the field facets 21. The field facets 21 generate a plurality of images of the intermediate focus on the pupil facets 23 respectively assigned thereto.

The field facets 21 are imaged, in each case by way of an assigned pupil facet 23, onto the reticle 7 in a manner such that they are superposed on one another for the purposes of illuminating the object field 5. The illumination of the object field 5 is in particular as homogeneous as possible. It can have a uniformity error of less than 2%. The field uniformity can be achieved by overlaying different illumination channels.

The illumination of the entrance pupil of the projection optical unit 10 can be geometrically defined by an arrangement of the pupil facets. It is possible to set the intensity distribution in the entrance pupil of the projection optical unit 10 by selecting the illumination channels, in particular the subset of pupil facets, which guide light. This intensity distribution is also referred to as illumination setting or illumination pupil filling.

A likewise preferred pupil uniformity in the region of sections of an illumination pupil of the illumination optical unit 4 which are illuminated in a defined manner may be achieved by a redistribution of the illumination channels.

Further aspects and details of the illumination of the object field 5 and in particular of the entrance pupil of the projection optical unit 10 are described hereinbelow.

The projection optical unit 10 may in particular have a homocentric entrance pupil. The latter can be accessible. It can also be inaccessible.

The entrance pupil of the projection optical unit 10 generally cannot be illuminated exactly via the pupil facet minor 22. The aperture rays often do not intersect at a single point when imaging the projection optical unit 10 which telecentrically images the center of the pupil facet mirror 22 onto the wafer 13. However, it is possible to find an area in which the spacing of the aperture rays, determined in pairwise fashion, is minimal. This surface area represents the entrance pupil or an area in real space that is conjugate thereto. In particular, this area has a finite curvature.

The projection optical unit 10 might have different poses of the entrance pupil for the tangential beam path and for the sagittal beam path. In this case, an imaging element, in particular an optical component part of the transfer optical unit, should be provided between the second facet mirror 22 and the reticle 7. With the aid of this optical element, the different poses of the tangential entrance pupil and the sagittal entrance pupil can be taken into account.

In the arrangement of the components of the illumination optical unit 4 illustrated in FIG. 1, the pupil facet mirror 22 is arranged in an area conjugate to the entrance pupil of the projection optical unit 10. The field facet minor 20 is tilted with respect to the object plane 6. The first facet mirror 20 is tilted with respect to an arrangement plane defined by the deflection minor 19. The first facet mirror 20 is arranged so as to be tilted with respect to an arrangement plane defined by the second facet mirror 22.

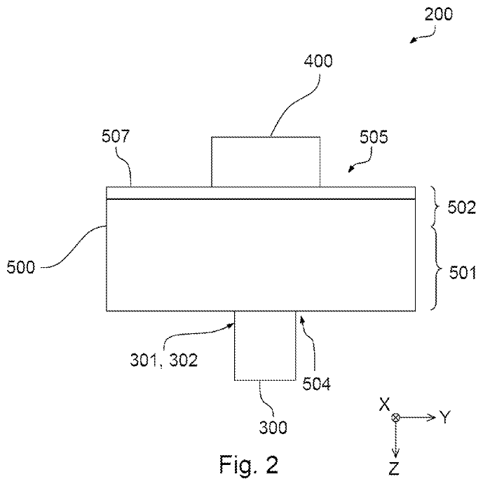

FIG. 2 shows an actuator-sensor device 200 for the lithography apparatus 1. The actuator-sensor device 200 comprises an actuator-sensor unit 300 having an actuator 301 and a sensor 302.

The actuator-sensor unit 300 is assigned to a facet 21, 23 of the facet mirror 20, 22. The facet 21, 23 may also be referred to as an optical element and the facet mirror 20, 22 as an optical module. The sensor 302 is suitable for detecting the pose (position and orientation) of the associated facets 21, 23. The actuator 301 is suitable for changing the pose of the associated facets 21, 23.

The actuator-sensor device 200 further comprises a control unit 400. The control unit 400 controls the actuator-sensor unit 300. For this purpose, the actuator-sensor unit 300 is electrically connected to the control unit 400. The control unit 400 can receive the sensor data, which are acquired by the sensor 302, and, taking into account the received sensor data, can generate control data and send the data to the actuator 301, which changes the position of the facet 21, 23 accordingly.

The actuator-sensor device 200 also comprises a supporting element 500, which supports the actuator-sensor unit 300 and the control unit 400. The actuator-sensor unit 300 is inserted from below (counter to the z-direction) into first receptacles 504 of the supporting element 500. For the actuator-sensor unit 300, a first receptacle 504 is provided, which is designed as an opening for receiving the actuator-sensor unit 300. The first receptacle 504 is provided on a first supporting side 501 of the supporting element 500.

The control unit 400 is arranged on a second supporting side 502 of the supporting element 500. The second supporting side 502 lies opposite the first supporting side 501. The supporting element 500 is at least partially located between the actuator-sensor unit 300 and the control unit 400. For receiving the control unit 400, the second supporting side 502 comprises a second receptacle 505, which will be explained in more detail below.

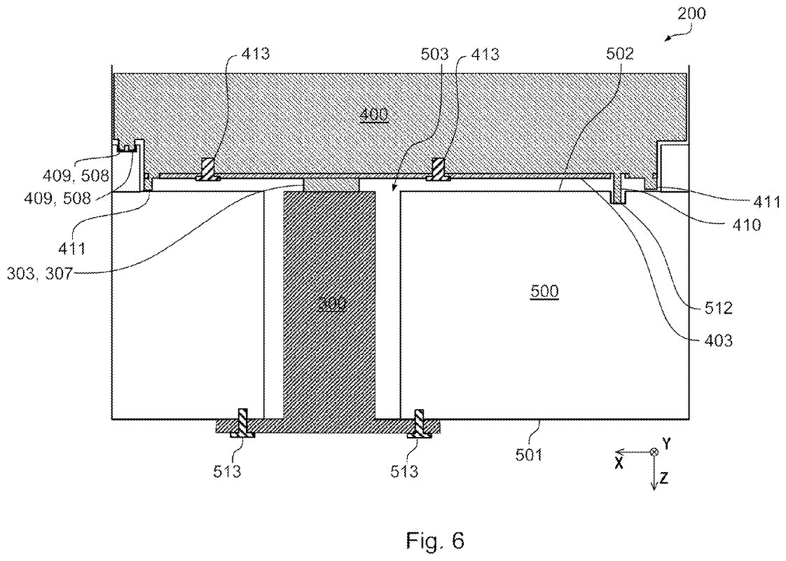

When mounting the control unit 400, the latter is inserted from above (along the z-direction) into the second receptacle 505. Between the first and second receptacles 504, 505, an opening 503 is provided in the supporting element 500, which opening pierces the supporting element 500 from the first supporting side 501 to the second supporting side 502 (FIG. 6). When the actuator-sensor unit 300 is supported by the first supporting side 501 and the control unit 400 is supported by the second supporting side 502, the two units 300, 400 are in contact with each other through the opening 503. This contact provides an electrical connection between the units 300, 400.

The control unit 400 is arranged in a vacuum-tight region. In this region, normal pressure prevails, while outside the region (i.e. where the optical module 20, 22 is arranged) there is a vacuum.

The control unit 400 can be removed from the supporting element 500 without being damaged. For this purpose, the control unit 400 to be repaired, tested and/or replaced can be removed from the second receptacle 505 counter to the z-direction. A new control unit 400 can be inserted in place of the removed one along the z-direction into the second receptacle 505.

The same applies to the actuator-sensor unit 300, which is also removable from the supporting element 500 without being damaged. Only the actuator-sensor unit 300 to be repaired, tested and/or replaced is removed along the z-direction from the first receptacle 504. A new actuator-sensor unit 300 can be inserted in place of the removed one counter to the z-direction into the first receptacle 504.

The actuator-sensor unit 300 can be advantageously replaced without having to remove the control unit 400, and vice versa. This significantly reduces maintenance costs.

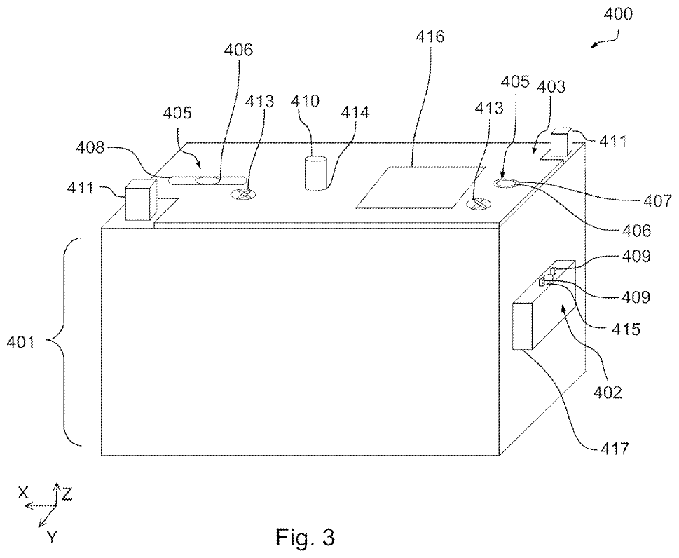

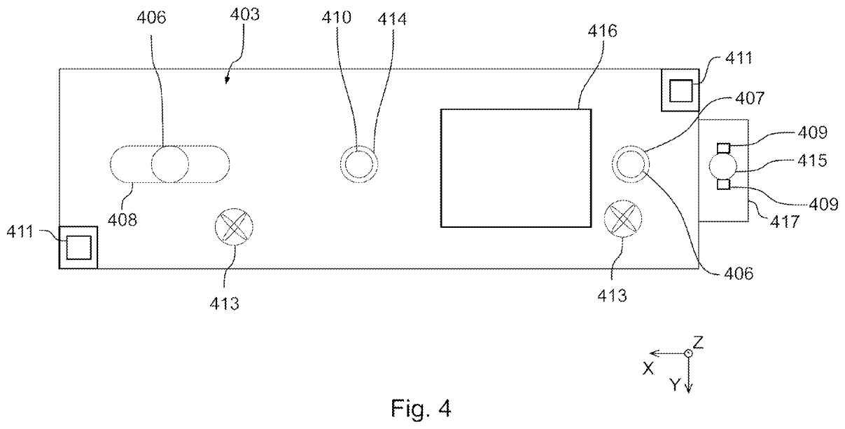

In the following, the control unit 400 will be described in more detail with reference to FIGS. 3 and 4. The control unit 400 comprises a main body 401, which is substantially cuboid and encloses electronic components. On an outer circumference of the main body 401, the latter comprises a heat sink 402, which is formed from copper.

On one side of the control unit 400, which faces the second supporting side 502 upon insertion into the supporting element 500, the control unit 400 comprises a printed circuit board 403. This is illustrated in FIG. 8 in top view. The printed circuit board 403 comprises a contact region 416 (second contact element). In other embodiments, the printed circuit board 403 may also comprise a plurality of contact regions 416. The second contact element 416 is a gold-coated region of the printed circuit board 403. The contact region 416 is used for electrically contacting the actuator-sensor unit 300.

When the control unit 400 is assembled, the printed circuit board 403 is placed onto the main body 401 counter to the z-direction. The printed circuit board 403 is connected to the main body 401 via a printed circuit board connection 405. The printed circuit board connection 405 comprises pins 406, holes 407, 408, and screws 413.

The pins 406 are provided on the main body 401, here on the heat sink 402, and formed in one piece of material therewith. The pins 406 are milled out of the heat sink. The holes 407, 408 in the printed circuit board 403 are provided so as to correspond to the pins 406. When assembling the printed circuit board 403 and the main body 401, the pins 406 are inserted into the holes 407, 408. The printed circuit board 403 is positioned using the two pins 406.

As shown in FIGS. 2 and 3, the hole 407 is a round hole (bore), while the hole 408 is an elongate hole. Via the hole 407, a translational movement of the printed circuit board 403 in the x- and y-directions along the heat sink 402 is blocked. Via a combination of pin 406 and elongate hole 408 on the left side, the rotation of the printed circuit board 403 on the heat sink 402 about the axis of the z-direction (Rz) is blocked by the left pin 406. The use of an elongate hole 408 does not overdetermine the positioning of the printed circuit board 403. In other words, small deviations in the dimensions and positionings of the holes 407, 408 can be compensated for by the elongate hole 408.

The translational movement of the printed circuit board 403 in the z-direction is prevented by two fastening screws 413. They firmly connect the printed circuit board 403 to the main body 401.

As shown in FIG. 3, the heat sink 402 furthermore comprises a positioning peg 410, which is milled out of the heat sink 402. The positioning peg 410 is guided through a peg hole 414 in the printed circuit board 403 and, when inserted into the supporting element 500, is guided into a peg receptacle 512 (FIG. 6). This causes the control unit 400 to be aligned relative to the supporting element 500.

To protect the printed circuit board 403 in the case of vertically concealed mounting into the supporting element 500, two diagonally opposite printed circuit board protection elements 411 are provided on the heat sink 402. The printed circuit board protection elements are projections that are milled out of the heat sink 402. The printed circuit board protection elements 411 protect the printed circuit board 403 from contact and thus damage with a surface or edge running parallel to the printed circuit board 403 during only partly guided assembly. Therefore, when mounting the control unit 400, only rotation about the x- and z-axes has to be prevented. In the event of a translational offset or rotation about the y-axis, the printed circuit board 403 is protected against damage by the printed circuit board protection elements 411 shown. In the illustration of FIG. 2, the printed circuit board 403 is introduced together with heat sink 402 from above into the supporting element 500. In this case, the printed circuit board 403 is protected by the special shape of the heat sink 402 against a collision with a contact surface of the supporting element 500. Instead of the two printed circuit board protection elements 411, more printed circuit board protection elements 411 (for example, four printed circuit board protection elements 411) may be arranged on the heat sink 402.

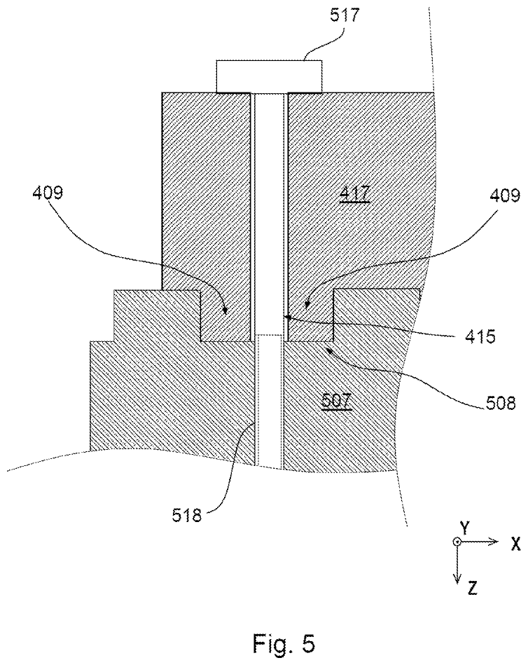

As shown in FIG. 2, the supporting element 500 comprises a metal strip 507 made of copper on the second supporting side 502. This is used to dissipate the heat from the heat sink 402. To connect the heat sink 402 to the metal strip 507, a projection 417 is provided on the side of the heat sink 402 (FIG. 3). On the top side of the heat sink there are two lugs 409, which are milled out of the heat sink 402 and are arranged on either side of a bore 415. The lugs 409 are inserted into lug receptacles 508, which are provided in the metal strip 507, during the mounting of the control unit 400. This is illustrated in FIG. 5. The connection of the lugs 409 to the lug receptacles 508 prevents rotation of the control unit 400 about the z-axis relative to the supporting element 500. The lug receptacles 508 are designed as bores 518 such that a screw 517 can be guided through the lug receptacle 508. The connection of lugs 409 and lug receptacles 508 is located higher, in the illustration of FIGS. 2 and 6, than the connection of peg 413 and peg receptacle 512.

FIG. 6 shows a schematic cross-sectional illustration of the actuator-sensor device 200. In the illustration of FIG. 6, a connection between an actuator-sensor unit 300 and a control unit 400 via the supporting element 500 can be seen. The actuator-sensor device 200 shown is suitable for the detachable electrical connection of the actuator-sensor unit 300 and the control unit 400, if these have tolerances in relative positioning with respect to each other because of their installation situation. In the illustration of FIG. 6, the actuator-sensor unit 300 is introduced from below (counter to the z-direction) into the supporting element 500, while the control unit 400 is introduced from above (along the z-direction). The two units 300, 400 are aligned and screwed to the supporting element 500 via fittings. An electrical connection is established between the units 300, 400, which can compensate for tolerances in the positioning of the individual components in any direction.

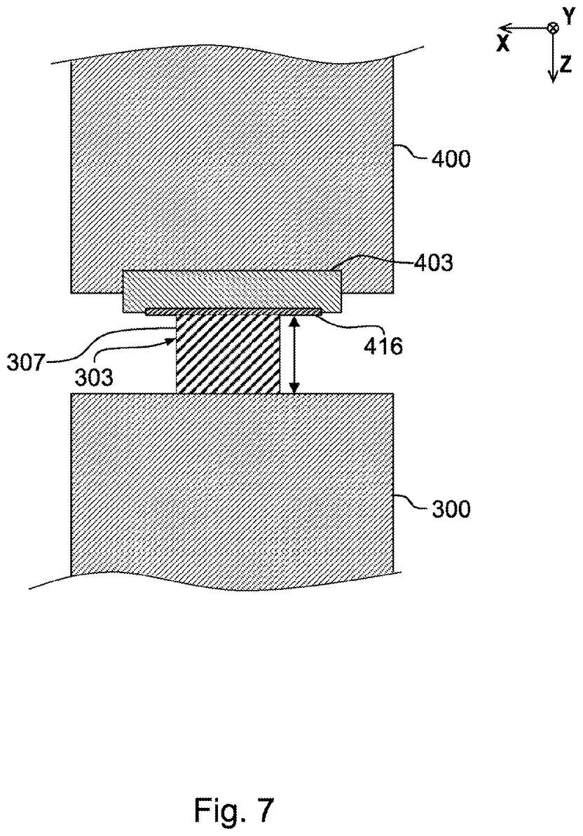

As shown in FIG. 6, a first contact element 300, which is designed as a spring contact pin 307, is provided for the electrical contacting of the actuator-sensor unit 303 and the control unit 400 on the actuator-sensor unit 300. The contact pin 307 contacts the second contact element 416 of the printed circuit board 403. As shown in FIG. 7, the area of the second contact element 416 along the XY plane is larger than the area of the first contact element 307 along the XY plane. This results in compensation for tolerances along the x- and y-directions. By the spring mounting of the spring contact pin 307, tolerances in the z-direction can be compensated for to a certain extent.

The actuator-sensor unit 300 is fastened to the supporting frame 500 with two fastening elements (screws) 513. An airtight seal of the vacuum-tight region in which the control unit 400 is arranged is made from the optical module 20, 22.

Although the present disclosure has been described with reference to exemplary embodiments, it is modifiable in various ways. It is possible, for example, to provide a plurality of actuator-sensor units 300 and/or a plurality of control units 400 in an actuator-sensor device 200. The actuator-sensor device 200 can also be inserted into a DUV lithography apparatus.

### LIST OF REFERENCE SIGNS

1 Projection exposure apparatus
2 Illumination system
3 Light source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
200 Actuator-sensor device
300 Actuator-sensor unit
301 Actuator
302 Sensor
303 First contact element
307 Spring contact pin
400 Control unit
401 Main body
402 Heat sink
403 Printed circuit board
405 Printed circuit board connection
406 Pin
407 Hole
408 Elongate hole
409 Lug
410 Positioning peg
411 Printed circuit board protection element
413 Screw
414 Peg hole
415 Hole
416 Second contact element
417 Projection
500 Supporting element
501 First supporting side
502 Second supporting side
503 Opening
504 First receptacle
505 Second receptacle
507 Metal strip
508 Lug receptacle
512 Peg receptacle
513 Fastening element
517 Screw
518 Hole
M1 Mirror
M2 Mirror
M3 Mirror
M4 Mirror
M5 Mirror
M6 Mirror

What is claimed is:

1. An actuator-sensor device, comprising:
an actuator-sensor unit comprising an actuator and a sensor;
a control unit electrically connected to the actuator-sensor unit; and
a supporting element having a first supporting side and a second supporting side facing the first supporting side,
wherein the actuator-sensor unit is supported on the first supporting side of the supporting element, and the control unit is supported on the second supporting side of the supporting element.

2. The actuator-sensor device of claim 1, wherein:
the supporting element has an opening piercing the supporting element from the first supporting side to the second supporting side; and
the actuator-sensor unit and the control unit are in contact through the opening so that the actuator-sensor unit and the control unit are electrically connected to each other.

3. The actuator-sensor device of claim 1, wherein:
the supporting element comprises, on its first supporting side, a first receptacle into which the actuator-sensor unit is at least partially inserted;
the supporting element comprises, on its second supporting side, a second receptacle into which the control unit is at least partially inserted; and
the first receptacle faces the second receptacle.

4. The actuator-sensor device of claim 1, wherein the actuator-sensor device is configured to be used in an optical module of a lithography apparatus, and the sensor is configured to detect a physical property of an optical element of the optical module.

5. The actuator-sensor device of claim 4, wherein the actuator is configured to change the physical property of the optical element.

6. The actuator-sensor device of claim 1, wherein the actuator-sensor device is configured to be used in an optical module of a lithography apparatus, and the actuator is configured to change a physical property of an optical element of the optical module.

7. The actuator-sensor device of claim 1, wherein the actuator-sensor device is configured to be used in an optical module of a lithography apparatus, and the sensor is configured to detect a pose of an optical element of the optical module.

8. The actuator-sensor device of claim 7, wherein the actuator-sensor device is configured to be used in an optical module of a lithography apparatus, and the actuator is configured to change the pose of the optical element.

9. The actuator-sensor device of claim 1, wherein the actuator-sensor unit is detachably connected to the first supporting side of the supporting element.

10. The actuator-sensor device of claim 9, wherein the control unit is detachably connected to the second supporting side of the supporting element.

11. The actuator-sensor device of claim 1, wherein:
the actuator-sensor unit comprises a first contact element;
the control unit comprises a printed circuit board comprising a second contact element; and
the supporting element supports the actuator-sensor unit and the control unit so that the first contact element is in contact with the second contact element.

12. The actuator-sensor device of claim 11, wherein the first contact element comprises a pin.

13. The actuator-sensor device of claim 11, wherein the first contact element comprises a spring contact pin.

14. The actuator-sensor device of claim 11, wherein:
the control unit comprises a main body comprising a printed circuit board connection configured to support the printed circuit board;
the printed circuit board connection comprises first and second pins;
the printed circuit board comprises first and second holes;
the hole receives the first pin;
the second hole receives the second pin; and
the first hole is an elongate hole.

15. The actuator-sensor device of claim 11, wherein the main body of the control unit comprises printed circuit board protection elements protruding laterally beyond the printed circuit board.

16. The actuator-sensor device of claim 1, wherein:
the supporting element comprises a metal strip configured to dissipate heat;
the control unit comprises a metal heat sink; and
the supporting element supports the actuator-sensor unit and the control unit so that the heat sink contacts the metal strip.

17. The actuator-sensor device of claim 16, wherein:
the heat sink comprises first and second lugs;
the metal strip comprises first and second receptacles; and
the supporting element supports the actuator-sensor unit and the control unit so that the first lug receptacle receives the first lug and the second lug receptacle receives the second lug.

18. The actuator-sensor device of claim 1, wherein:
the control unit comprises a positioning peg;
the supporting element comprises a peg receptacle; and
the supporting element supports the control unit so that the peg receptacle receives the positioning peg.

19. An apparatus, comprising:
an actuator-sensor device,
wherein the apparatus is a lithography apparatus.

20. The apparatus of claim 19, wherein the apparatus comprises an optical module comprising an optical element, and the actuator is configured to control a position of the optical element.
